(19) United States
(12) Patent Application Publication
(10) Pub. No.: US 2024/0014112 A1
(43) Pub. Date: Jan. 11, 2024

(54) ELECTRONIC COMPONENT EMBEDDED SUBSTRATE

(71) Applicant: TDK Corporation, Tokyo (JP)

(72) Inventors: Kazutoshi TSUYUTANI, Tokyo (JP); Tadashi MITO, Tokyo (JP); Eisuke YONEKURA, Tokyo (JP); Michitaka OKAZAKI, Tokyo (JP); Masumi KAMEDA, Tokyo (JP)

(21) Appl. No.: 18/249,862

(22) PCT Filed: Oct. 22, 2021
(86) PCT No.: PCT/JP2021/039046

§ 371 Date: Apr. 20, 2023

(30) Foreign Application Priority Data
Oct. 30, 2020 (JP) 2020-183053
Oct. 30, 2020 (JP) 2020-183054

(51) Int. Cl. H01L 23/498; H01L 23/538; H01L 23/14; H01L 21/48

(52) U.S. Cl. CPC H01L 23/49822; H01L 23/49827; H01L 23/5389; H01L 23/142; H01L 21/4857

(57) ABSTRACT

An electronic component embedded substrate includes conductor layers L1 to L3, insulating layers 112 and 113 provided between the conductor layers L2 and L3, an insulating layer 114 provided between the conductor layers L1 and L2, a semiconductor embedded in the insulating layers 112 and 113, a via conductor 142 filling a via V, and a via conductor 143 filling a via 143a. The via 143a is provided at such a position that overlaps the via V and is shallower than the via V. The inner wall of the via 143a is larger in surface roughness than the inner wall of the via V. This makes voids less likely to occur in the via conductor 142 filling the deep via V and enhances adhesion between the via conductor 143 and the shallow via 143a that the via conductor 143 fills.

### TECHNICAL FIELD

The present invention relates to an electronic component embedded substrate and, more particularly, to an electronic component embedded substrate having a multilayer wiring structure.

### BACKGROUND ART

As an electronic component embedded substrate having a multilayer wiring structure, an electronic component embedded substrate described in Patent Document 1 is known. The electronic component embedded substrate described in Patent Document 1 has a plurality of vias having different depths and via conductors filling the respective vias. Further, the electronic component embedded substrate described in Patent Document 1 has vias penetrating an insulating layer embedding therein an electronic component and via conductors filling the respective vias. The vias each have a shape reduced in diameter in the depth direction.

### CITATION LIST

### Patent Document

[Patent Document 1] JP 2020-107877A

### SUMMARY OF THE INVENTION

### Problem to be Solved by the Invention

However, disadvantageously, the via conductor formed in a deep via is likely to have voids and, on the other hand, adhesiveness between the via conductor and a shallow via becomes inferior. Further, in a case where the via has a shape in which the diameter thereof simply decreases in the depth direction, when the distance between the via and an electronic component is small or heat caused by the operation of the electronic component is high, connection reliability at the bottom portion of the via conductor may deteriorate due to heat.

An object of the present invention is to prevent voids from occurring in a via conductor formed in a deep via and to improve adhesiveness between a shallow via and the via conductor in an electronic component embedded substrate having a multilayer wiring structure. Another object of the present invention is to provide an electronic component embedded substrate in which connection reliability at the bottom portion of the via conductor is improved.

### Means for Solving the Problem

A electronic component embedded substrate according to the present invention includes: first and second insulating layers; an electronic component embedded between the upper surface of a first insulating layer and the upper surface of a second insulating layer; a first conductor layer provided on the lower surface of the first insulating layer; a second conductor layer provided on the upper surface of the second insulating layer; a third insulating layer covering the second conductor layer; a third conductor layer provided on the surface of the third insulating layer; a first via conductor filling a first via penetrating the first and second insulating layers and connecting the first and second conductor layers; and a second via conductor filling a second via penetrating the third insulating layer and connecting the second and third conductor layers. The second via is positioned at such a position as to overlap the first via and is smaller in length in the depth direction thereof than the first via. The inner wall of the second via is larger in surface roughness than the inner wall of the first via.

According to the present invention, voids are less likely to occur in the first via conductor filling the deep first via, and adhesion between the second via conductor and the shallow second via that the second via conductor fills can be enhanced.

In the present invention, the first and second insulating layers may each be made of a resin material not containing a core material, and the third insulating layer may be a core layer obtained by impregnating a core material with a resin material. This prevents embedding of the electronic component from being hindered by the core material and makes voids less likely to occur during formation of the first via conductor by electrolytic plating even when the first via has a large depth.

In the present invention, the thickness of the third insulating layer may be locally increased at a part overlapping the first via conductor, and a part of the third insulating layer that contacts the upper surface of the first via conductor may be constituted by a resin material not containing a core material. This allows the resin material oozed from the core material to be housed in the upper portion of the first via conductor.

In the present invention, an upper section of the first via that is positioned on the side close to the upper surface of the second insulating layer may have a shape reduced in diameter in the depth direction, and a lower section of the first via that is positioned on the side close to the lower surface of the first insulating layer may have a first section increased in diameter in the depth direction and a second section positioned closer to the lower surface of the first insulating layer than the first section and reduced in diameter in the depth direction. Since the lower section of the first via has such first and second sections, a sufficient volume of the first via conductor at its bottom portion can be ensured, and peeling is less likely to occur at the interface between the first via conductor and the first insulating layer. Thus, even in a case where the distance between the bottom portion of the first via conductor and the electronic component is small or where heat generated by the operation of the electronic component is high, connection reliability at the bottom portion of the first via conductor can be improved. Further, at least a part of the first section may be provided in the second insulating layer, and at least a part of the second section may be provided in the first insulating layer. Further, the boundary between the first and second sections may coincide with the boundary between the first and second insulating layers.

In the present invention, the first and second insulating layers may be made of the same resin material. This can reduce material cost.

### Advantageous Effects of the Invention

As described above, according to the present invention, in an electronic component embedded substrate having a multilayer wiring structure, it is possible to prevent voids from occurring in a via conductor formed in a deep via and to improve adhesiveness between a shallow via and the via conductor. Further, there can be provided an electronic component embedded substrate in which connection reliability at the bottom portion of the via conductor is improved.

### BRIEF DESCRIPTION OF DRAWINGS

FIG. 1 is a schematic cross-sectional view for explaining the structure of an electronic component embedded substrate 100 according to an embodiment of the present invention.

FIG. 2 is an enlarged cross-sectional view of an area where the via conductors 142 and 143 are formed.

FIG. 3 is a process view for explaining the manufacturing method for the electronic component embedded substrate 100.

FIG. 4 is a process view for explaining the manufacturing method for the electronic component embedded substrate 100.

FIG. 5 is a process view for explaining the manufacturing method for the electronic component embedded substrate 100.

FIG. 6 is a process view for explaining the manufacturing method for the electronic component embedded substrate 100.

FIG. 7 is a process view for explaining the manufacturing method for the electronic component embedded substrate 100.

FIG. 8 is a process view for explaining the manufacturing method for the electronic component embedded substrate 100.

FIG. 9 is a process view for explaining the manufacturing method for the electronic component embedded substrate 100.

FIG. 10 is a process view for explaining the manufacturing method for the electronic component embedded substrate 100.

FIG. 11 is a process view for explaining the manufacturing method for the electronic component embedded substrate 100.

FIG. 12 is a process view for explaining the manufacturing method for the electronic component embedded substrate 100.

FIG. 13 is an enlarged cross-sectional view of an area according to a modification where the via conductors 142 and 143 are formed.

FIG. 14 is a schematic cross-sectional view for explaining the structure of an electronic component embedded substrate 200 according to a modification.

### MODE FOR CARRYING OUT THE INVENTION

Hereinafter, preferred embodiments of the present invention will be described in detail with reference to the accompanying drawings.

### Mode for Carrying Out the Invention

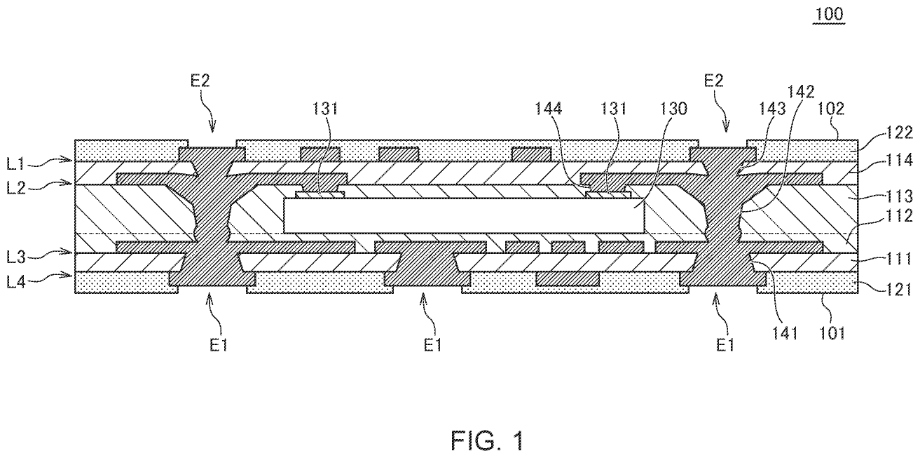

FIG. 1 is a schematic cross-sectional view for explaining the structure of an electronic component embedded substrate 100 according to an embodiment of the present invention.

As illustrated in FIG. 1, the electronic component embedded substrate 100 according to the present embodiment has four insulating layers 111 to 114 and conductor layers L1 to L4 positioned on the surfaces of the respective four insulating layers 114 to 111. Although not particularly limited, the lowermost insulating layer 111 and the uppermost insulating layer 114 may each be a core layer obtained by impregnating a core material such as glass fiber with a resin material such as epoxy. On the other hand, the insulating layers 112 and 113 may each be made of a resin material not containing a core material such as glass cloth. Particularly, the insulating layers 111 and 114 are preferably smaller in thermal expansion coefficient than the insulating layers 112 and 113.

The lowermost insulating layer 111 and the conductor layer L4 formed on the surface thereof may be partly covered with a solder resist 121. Similarly, the uppermost insulating layer 114 and the conductor layer L1 formed on the surface thereof may be partly covered with a solder resist 122. Although not particularly limited, the solder resist 121 constitutes a lower surface 101 of the electronic component embedded substrate 100, and the solder resist 122 constitutes an upper surface 102 of the electronic component embedded substrate 100.

As illustrated in FIG. 1, the electronic component embedded substrate 100 according to the present embodiment has a semiconductor IC 130 embedded between the upper surface of the insulating layer 112 and the lower surface of the insulating layer 113. A plurality of terminal electrodes 131 are provided on the main surface of the semiconductor IC 130. Although only one semiconductor IC 130 is illustrated in FIG. 1, two or more semiconductor ICs 130 may be embedded. Further, although the semiconductor IC 130, which is particularly problematic in terms of heat generation, is incorporated in the present embodiment, an electronic component to be incorporated in the electronic component embedded substrate 100 is not limited to this, and a passive component such as a capacitor or an inductor may be incorporated.

The conductor layer L1 is provided on the upper surface of the insulating layer 114. A part of the conductor layer L1 that is not covered with the solder resist 122 constitutes an external terminal E2 of the electronic component embedded substrate 100.

The conductor layer L2 is provided on the upper surface of the insulating layer 113, and the surface thereof is covered with the insulating layer 114. The conductor layers L1 and L2 are partly connected to each other through a via conductor 143 penetrating the insulating layer 114.

The conductor layer L3 is provided on the lower surface of the insulating layer 112, and the surface thereof is covered with the insulating layer 111. The conductor layers L2 and L3 are partly connected to each other through a via conductor 142 penetrating the insulating layers 113 and 112. A part of the conductor layer L2 and the terminal electrode 131 of the semiconductor IC 130 are connected to each other through a via conductor 144 penetrating the insulating layer 113.

The conductor layer L4 is provided on the lower surface of the insulating layer 111. A part of the conductor layer L4 that is not covered with the solder resist 121 constitutes an external terminal E1 of the electronic component embedded substrate 100.

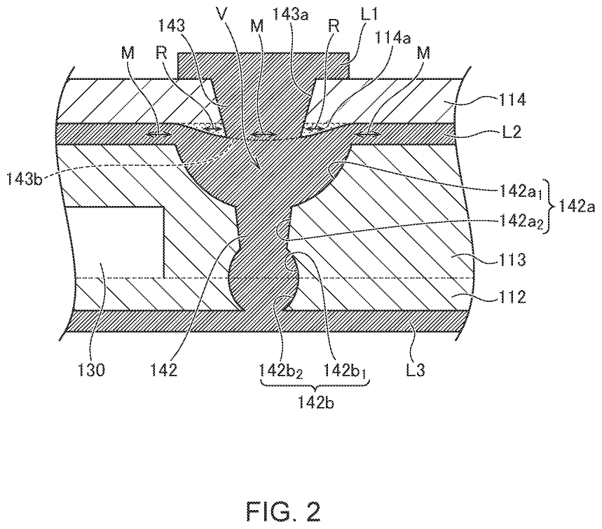

FIG. 2 is an enlarged cross-sectional view of an area where the via conductors 142 and 143 are formed.

As illustrated in FIG. 2, the via conductor 142 fills a via V penetrating the insulating layers 113 and 112 to connect the conductor layers L2 and L3. The via V has an upper section 142a provided in the insulating layer 113 and a lower section 142b positioned closer to the conductor layer L3 than the upper section 142a. As described later, the via V is formed starting from the upper surface side of the insulating layer 113, and thus the depth direction of the via V is defined by a direction directed from the conductor layer L2 to the conductor layer L3.

The upper section 142a has a shape reduced in diameter in the depth direction and includes a section 142a₁ (conductor layer L2 side) and a section 142a₂ (insulating layer 112 side) which are mutually different in shape. In the example illustrated in FIG. 2, the angle of the inner wall of the via V is closer to a vertical state in the section 142a₂ than in the upper section 142a. In other words, the reduction in the diameter of the section 142a₁ per unit depth is larger than the reduction in the diameter of the section 142a₂ per unit depth. Although not particularly limited, the inner wall of the section 142a₁ is curved in the example illustrated in FIG. 2.

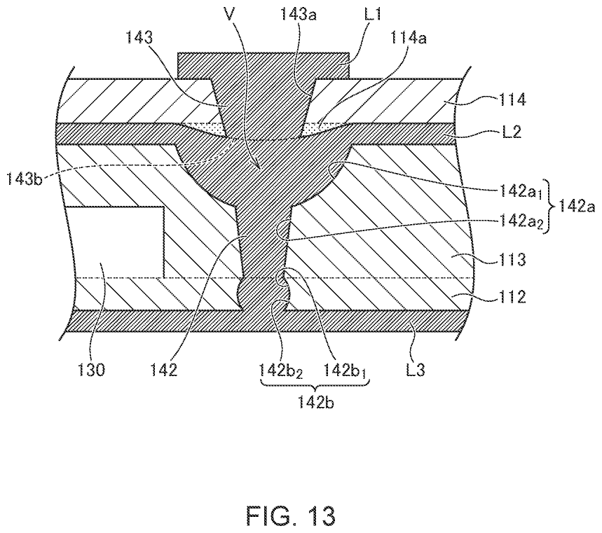

The lower section 142b includes a section 142b₁ connected to the upper section 142a and enlarged in diameter in the depth direction and a section 142b₂ positioned on the side close to the conductor layer L3 and reduced in diameter in the depth direction. That is, when viewed in the depth direction, the lower section 142b has a barrel shape in which the diameter is once increased and then reduced. In the example illustrated in FIG. 2, the section 142b₁ is provided in the insulating layer 113, and the section 142b₂ is provided in the insulating layer 112. In this case, the boundary between the sections 142b₁ and 142b₂ is positioned at the boundary between the insulating layers 113 and 112. Thus, the via V has a shape in which the diameter is locally reduced in the vicinity of the interface between the insulating layers 113 and 112. However, in the present invention, the boundary between the sections 142b₁ and 142b₂ need not necessarily coincide with the boundary between the insulating layers 113 and 112 and, as illustrated in FIG. 13, the boundary between the sections 142a and 142b may coincide with the boundary between the insulating layers 113 and 112. In this case, the upper and lower sections 142a and 142b penetrate the insulating layers 113 and 112, respectively.

The via conductor 142 fills the inside of the via V such a shape as described above. The via conductor 142 has a filled-via structure wherein it fills not only the inner wall portion of the via V but also substantially the entire space formed by the via V. Thus, unlike when the via conductor 142 has a conformal via structure, another via (in this case, via conductor 143) can be disposed immediately above the via conductor 142. Further, the insulating layer 113 has a larger thickness than the insulating layer 112, and the upper section 142a positioned on the side close to the insulating layer 113 has a shape reduced in diameter in the depth direction, so that it is possible to bring the semiconductor IC 130 mounted on the surface of the insulating layer 112 closer to the via conductor 142, contributing to high density mounting.

However, disposing the semiconductor IC 130 close to the via conductor 142 may apply heat stress to the via conductor 142 particularly when the semiconductor IC 130 has large heat generation, which may cause peeling at the bottom of the via conductor 142. However, in the present embodiment, the lower section 142b positioned on the side close to the insulating layer 112 has a barrel shape formed by the two sections 142b₁ and 142b₂ having mutually different shapes, so that a sufficient volume of the via conductor 142 filling the lower section 142b is ensured, and high heat dissipation performance obtained thereby can alleviate the heat stress. In addition, the bottom portion of the via conductor 142 assumes an anchor shape, thus enhancing adhesion between the via conductor 142 and the insulating layer 112, which can prevent the occurrence of voids.

Although the via conductor 142 has a filled-via structure, the upper surface thereof is not completely flat but has a slight recess. As a result, the thickness of the insulating layer 114 is locally increased at a part overlapping the via conductor 142. A part of the insulating layer 114 that is locally increased in thickness, i.e., a part thereof that contacts the upper surface of the via conductor 142 is constituted by a resin material 114a not containing a core material. The upper surface of the via conductor 142 refers to the surface of the conductor layer L2 existing at a portion overlapping the via V in a plan view. As described above, the recess in the upper surface of the via conductor 142 functions as a housing part for the resin material oozed from the core material constituting the insulating layer 114. Further, the recessed curve of a bottom part 143b of the via conductor 143 makes stress due to a difference between a thermal expansion coefficient M of the conductor layer L2 and a thermal expansion coefficient R of the insulating layer 114 less likely to be applied to the bottom part 143b (interface between the via conductors 142 and 143), thereby improving connection reliability. More specifically, when the bottom part 143b of the via conductor 143 is flat, horizontal stress due to the difference between the thermal expansion coefficient M and the thermal expansion coefficient R concentrates on the bottom part 143b, while when the bottom part 143b of the via conductor 143 is curved, the conductor layer L2 exists at the same height position as the bottom part 143b to reduce the volume of the insulating layer 114 existing around the bottom part 143b, thereby reducing stress to be applied to the bottom part 143b.

On the other hand, the via conductor 143 fills a via 143a penetrating the insulating layer 114 to connect the conductor layers L1 and L2. The via 143a is formed at a position overlapping the via V and is shorter in length in the depth direction than the via V. Therefore, the contact area between the inner wall of the via 143a and the via conductor 143 is small to make peeling at the interface therebetween likely to occur; however, in the present embodiment, the surface roughness of the inner wall of the via 143a is designed larger than the surface roughness of the inner wall of the via V, whereby adhesion of the via conductor 143 is enhanced. A method of increasing the surface roughness of the inner wall of the via 143a may include making a core material such as glass fiber contained in the insulating layer 114 protrude from the inner wall of the via 143a and roughening the inner wall in a formation process of the via 143a or forming the via 143a under conditions that the inner wall thereof is roughened. On the other hand, the inner wall of the via V longer in the depth direction has a small surface roughness, so that when the via conductor 142 is formed through electrolytic plating, voids are less likely to occur at the interface between the via V and the via conductor 142.

The following describes a manufacturing method for the electronic component embedded substrate 100 according to the present embodiment.

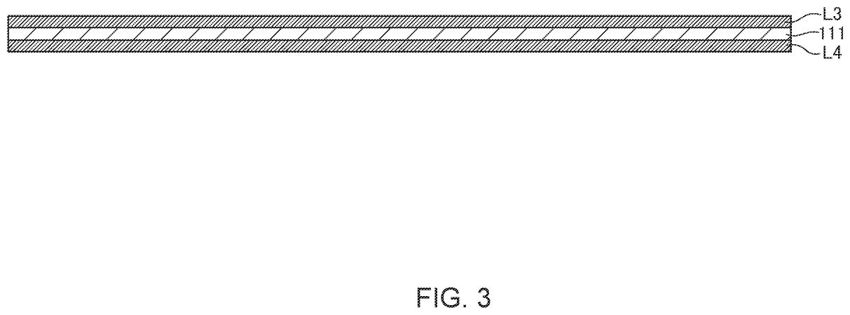

FIGS. 3 to 12 are process views for explaining the manufacturing method for the electronic component embedded substrate 100 according to the present embodiment.

First, as illustrated in FIG. 3, a base material (workboard) obtained by bonding the conductor layers L3 and L4 made of a Cu foil or the like to both surfaces of the insulating layer 111 containing a core material such as glass fiber, i.e., a double-sided CCL (Copper Clad Laminate) is prepared. The core material contained in the insulating layer 111 is desirably 40 μm or more in thickness so as to have adequate rigidity for easy handling. The material of the conductor layers L3 and L4 is not particularly limited to a specific one and may be a metal conductive material such as, in addition to Cu described above, Au, Ag, Ni, Pd, Sn, Cr, Al, W, Fe, Ti or a SUS material. Among them, Cu is preferably used in terms of conductivity and cost. The same applies to the conductor layers L1 and l2 to be described later.

The resin material for forming the insulating layer 111 is not particularly limited as long as it can be formed into a sheet shape or a film shape, and examples thereof include: a single element selected from the group consisting of vinyl benzyl resin, polyvinyl benzyl ether compound resin, bismaleimide triazine resin (BT resin), polyphenylene ether (polyphenylene ether oxide) resin (PPE, PPO), cyanate ester resin, epoxy+activated ester curing resin, polyphenylene ether resin (polyphenylene oxide resin), curable polyolefin resin, benzo cyclobutene resin, polyimide resin, aromatic polyester resin, aromatic liquid crystal polyester resin, polyphenylene sulfide resin, polyether imide resin, polyacrylate resin, polyetheretherketone resin, fluororesin, epoxy resin, phenolic resin, and benzoxazine resin in addition to glass epoxy; a material obtained by adding, to one of the above-listed resins, silica, talc, calcium carbonate, magnesium carbonate, aluminum hydroxide, magnesium hydroxide, aluminum borate whiskers, potassium titanate fiber, alumina, glass flakes, glass fiber, tantalum nitride, aluminum nitride, or the like; and a material obtained by adding, to one of the above-listed resins, metal oxide powder containing at least one metal selected from the group consisting of magnesium, silicon, titanium, zinc, calcium, strontium, zirconium, tin, neodymium, samarium, aluminum, bismuth, lead, lanthanum, lithium and tantalum, and these examples may be selectively used as appropriate from the viewpoints of electrical characteristics, mechanical characteristics, water absorption properties, reflow durability, etc. Further, examples of the core material included in the insulating layer 111 include a material blended with, e.g., resin fiber such as glass fiber or aramid fiber. The resin material for forming the insulating layers 112 to 114 described later may be the same resin material of the insulating layer 111.

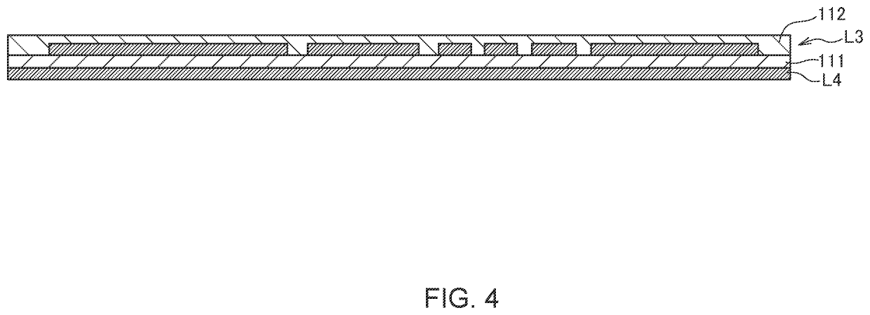

Then, as illustrated in FIG. 4, the conductor layer L3 is patterned using, for example, a known method such as a photolithography method. Then, for example, an uncured (B stage) resin sheet or the like is laminated by vacuum pressure bonding or the like on the surface of the insulating layer 111 so as to embed therein the patterned conductor layer L3 to thereby form the insulating layer 112.

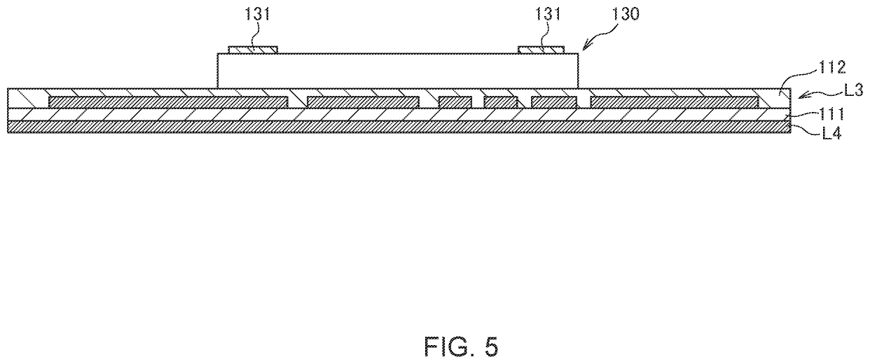

Then, as illustrated in FIG. 5, the semiconductor IC 130 is placed on the surface of the insulating layer 112. The semiconductor IC 130 is face-up mounted such that the main surface thereof from which the terminal electrode 131 is exposed faces upward. As described above, the semiconductor IC 130 may be subjected to thickness reduction. Specifically, the thickness of the semiconductor IC 130 is set to, for example, 200 μm or less, preferably, about 50 μm to 100 μm. In this case, when considering cost, a large number of semiconductor ICs 130 are preferably collectively machined in a wafer state. The machining order is: the back surface of the wafer is ground; and the wafer is diced and separated into individual semiconductor ICs 130. Alternatively, when the wafer is cut and separated by dicing into individual semiconductor ICs 130 or subjected to half-cut before polishing for thickness reduction, the back surface of the semiconductor IC 130 may be ground with the main surface thereof covered with a thermosetting resin or the like. Thus, insulating film grinding, electronic component back surface grinding, and dicing may be carried out in various orders. Further, a grinding method for the back surface of the semiconductor IC 130 may include surface roughening methods by etching, plasma treatment, laser processing, blasting, grinding using a grinder, buffing, chemical treatment, and the like. With these methods, it is possible not only to reduce the thickness of the semiconductor IC 130 but also to improve adhesion to the insulating layer 112.

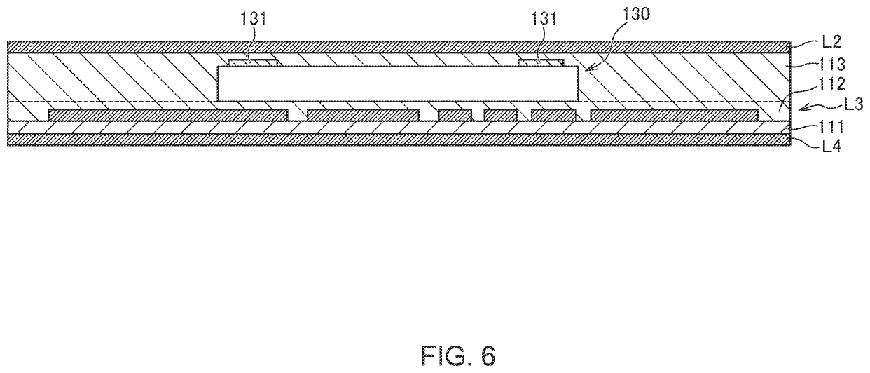

Then, as illustrated in FIG. 6, the insulating layer 113 and conductor layer L2 are formed so as to cover the semiconductor IC 130. Preferably, the insulating layer 113 is formed as follows: after application of an uncured or semi-cured thermosetting resin, the resin (when it is uncured resin) is semi-cured by heating, and then the semi-cured resin and conductor layer L2 are pressed together by a pressing means to obtain a cured insulating layer 113. The insulating layer 113 is preferably a resin sheet not containing fiber that hinders embedding of the semiconductor IC 130. This enhances adhesion of the insulating layer 113 with respect to the conductor layer L2, insulating layer 112, and semiconductor IC 130. The material used for the insulating layer 113 may be the same as that for the insulating layer 112.

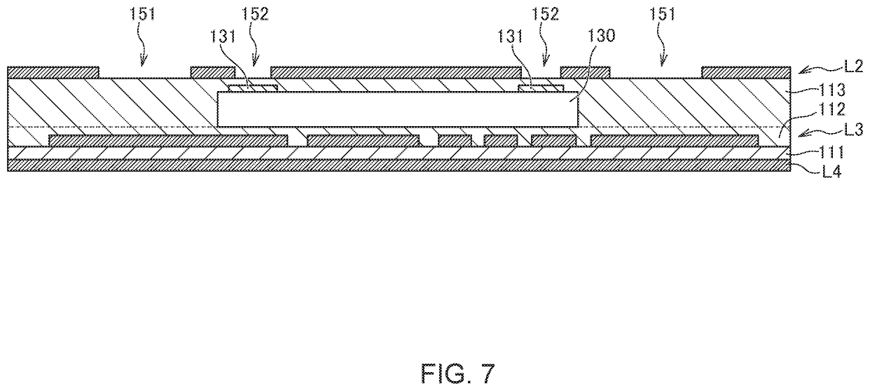

Then, as illustrated in FIG. 7, a part of the conductor layer L2 is etching-removed by using a known method such as a photolithography method to form openings 151 and 152 for exposing the insulating layer 113. The opening 151 is formed at such a position as not to overlap the semiconductor IC 130 and to overlap the conductor layer L3, and the opening 152 is formed at such a position as to overlap the terminal electrode 131 of the semiconductor IC 130.

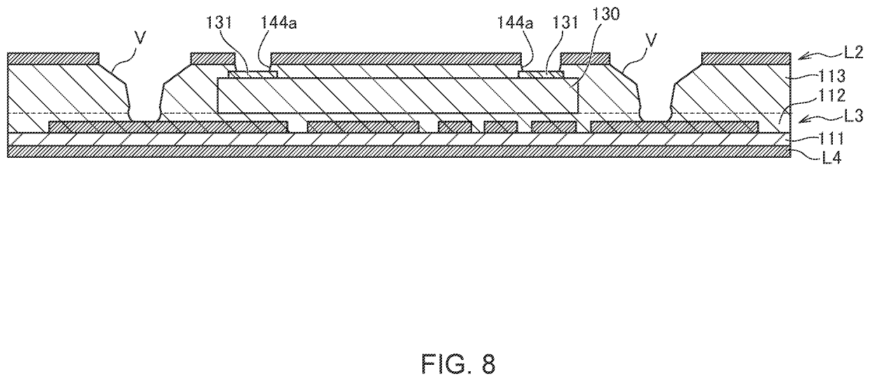

Then, as illustrated in FIG. 8, laser processing and/or blasting is applied to form the via V in the insulating layers 112 and 113 and to form a via 144a in the insulating layer 113. The via V can be formed into the shape as illustrated in FIG. 2 depending on the conditions of laser processing and blasting. For example, laser light is irradiated onto the center portion of the opening 151 to form a barrel-shaped via including the sections 142b₁ and 142b₂, and then blasting is applied entirely with the conductor layer L2 as a mask to form the sections 142b₁ and 142b₂ into the shapes illustrated in FIG. 2. By using a resin material not containing a core material such as glass fiber as the material of the insulating layers 112 and 113, the surface roughness of the inner wall of the via V can be reduced.

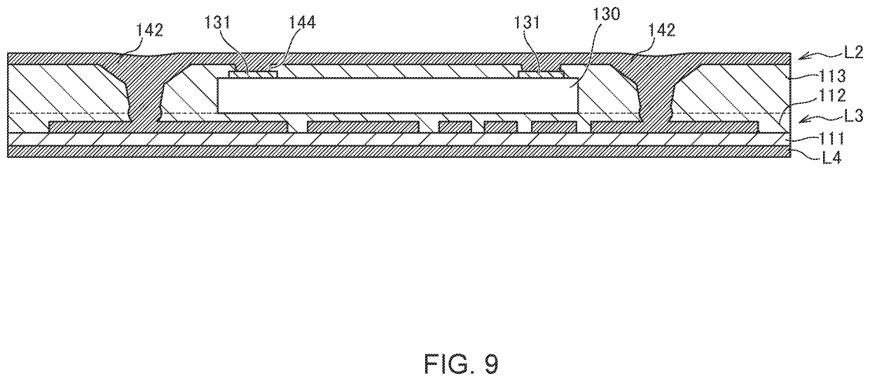

Then, as illustrated in FIG. 9, electroless plating and electrolytic plating are applied to form the via conductors 142 and 144. Although the via conductor 142 is formed so as to fill the deep via V and is thus likely to have voids, making the surface roughness of the inner wall of the via V sufficiently small can prevent the occurrence of such voids.

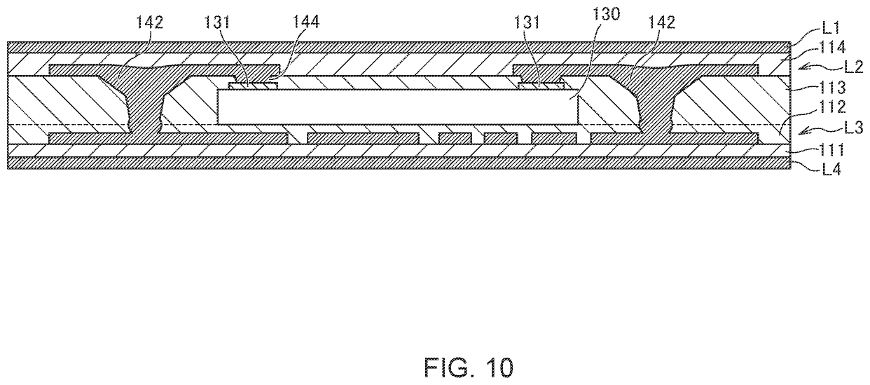

Then, as illustrated in FIG. 10, the conductor layer L2 is patterned using a known method, and then a sheet having the insulating layer 114 and conductor layer L1 laminated thereon is hot-pressed under vacuum so as to embed therein the conductor layer L2. The material and thickness of the insulating layer 114 may be the same as those of the insulating layer 111.

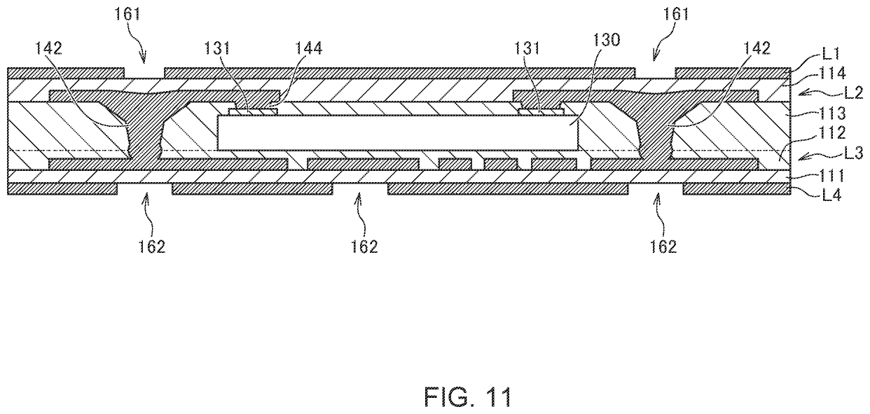

Then, as illustrated in FIG. 11, a part of the conductor layer L1 and a part of the conductor layer L4 are etching-removed by using a known method such as a photolithography method to form an opening 161 for exposing the insulating layer 114 and an opening 162 for exposing the insulating layer 111. The opening 161 is formed at such a position as to overlap the via conductor 142.

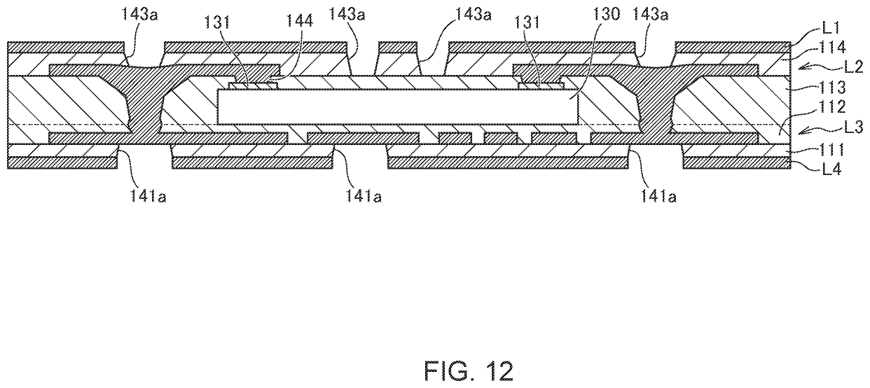

Then, as illustrated in FIG. 12, known laser processing or blasting is applied to the openings 161 and 162 to remove the insulating layers 111 and 114 at respective positions not covered with the conductor layers L1 and L4. As a result, the via 143a is formed in the insulating layer 114 at a position corresponding to the opening 161 of the conductor layer L1 to expose the upper surface of the via conductor 142. Similarly, the via 141a is formed in the insulating layer 111 at a position corresponding to the opening 162 of the conductor layer L4. The conditions of the laser processing or blasting are set so as to make the surface roughness of the inner walls of the vias 141a and 143a larger than that of the inner wall of the via V.

Then, electroless plating and electrolytic plating are applied to form the via conductors 141 and 143 inside the vias 141a and 143a, respectively, and then the conductor layers L1 and L4 are patterned using a known method such as a photolithography method to form the solder resists 121 and 122 each at a predetermined planar position, whereby the electronic component embedded substrate 100 illustrated in FIG. 1 is completed.

As described above, in the present embodiment, the sections 142b₁ and 142b₂ of the via V that are positioned on the side close to the conductor layer L3 form a barrel shape, so that a sufficient volume of the via conductor 142 to fill the lower section 142b is ensured, and high heat dissipation performance obtained thereby can alleviate heat stress. In addition, the bottom portion of the via conductor 142 assumes an anchor shape, thus enhancing adhesion between the via conductor 142 and the insulating layer 112, which can prevent the occurrence of voids.

Further, in the present embodiment, the surface roughness of the inner wall of the via V penetrating the insulating layers 112 and 113 is small, and the surface roughness of the inner walls of the vias 141a and 143a penetrating respectively the insulating layers 111 and 114 is large, so that voids are less likely to occur in the via conductor 142 to fill the via V, and adhesion of the via conductors 141 and 143 to the respective vias 141a and 143 that they fill can be enhanced.

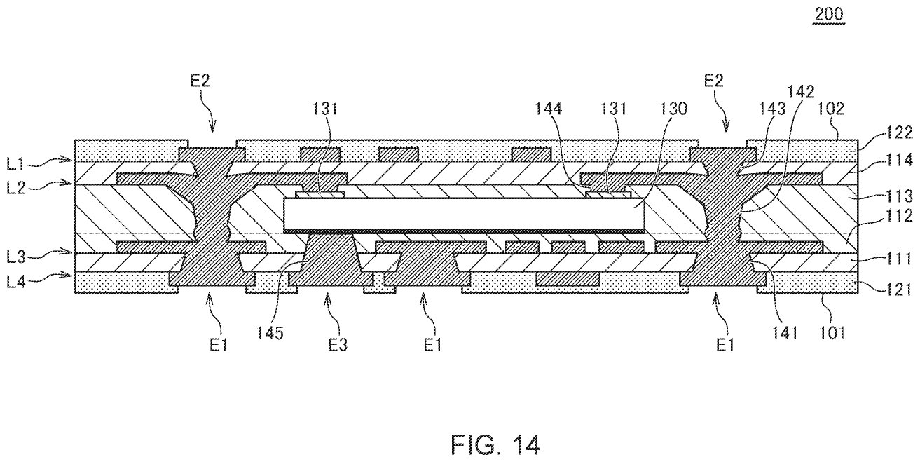

FIG. 14 is a schematic cross-sectional view for explaining the structure of an electronic component embedded substrate 200 according to a modification.

The electronic component embedded substrate 200 illustrated in FIG. 14 differs from the electronic component embedded substrate 100 illustrated in FIG. 1 in that a heat-dissipating via conductor 145 penetrating the insulating layers 111 and 112 and contacting the back surface of the semiconductor IC 130 is additionally provided. The surface of the via conductor 145 constitutes a heat dissipating terminal E3. With this configuration, heat generated from the semiconductor IC 130 is dissipated outside efficiently, so that heat stress to be applied to the via conductor 142 is alleviated to further improve connection reliability.

It is apparent that the present invention is not limited to the above embodiments, but may be modified and changed without departing from the scope and spirit of the invention.

### REFERENCE SIGNS LIST

100, 200 electronic component embedded substrate
101 lower surface of the electronic component embedded substrate
102 upper surface of the electronic component embedded substrate
111-114 insulating layer
114a resin material
121, 122 solder resist
122 solder resist
130 semiconductor IC
131 terminal electrode
141-145 via conductor
141a, 143a, 144a, V via
141-144 via conductor
142a upper section
142b lower section
142a₁, 142a₂, 142b₁, 142b₂ section
151, 152, 161, 162 opening
E1, E2 external terminal
E3 heat dissipating terminal
L1-L4 conductor layer

1. A electronic component embedded substrate comprising:
first and second insulating layers;
an electronic component embedded between an upper surface of a first insulating layer and an upper surface of a second insulating layer;
a first conductor layer provided on a lower surface of the first insulating layer;
a second conductor layer provided on the upper surface of the second insulating layer;
a third insulating layer covering the second conductor layer;
a third conductor layer provided on a surface of the third insulating layer;
a first via conductor filling a first via penetrating the first and second insulating layers and connecting the first and second conductor layers; and
a second via conductor filling a second via penetrating the third insulating layer and connecting the second and third conductor layers,
wherein the second via is positioned at such a position as to overlap the first via,
wherein the second via is smaller in length in a depth direction thereof than the first via, and
wherein an inner wall of the second via is larger in surface roughness than an inner wall of the first via.

2. The electronic component embedded substrate as claimed in claim 1,
wherein each of the first and second insulating layers is made of a resin material not containing a core material, and
wherein the third insulating layer is a core layer obtained by impregnating a core material with a resin material.

3. The electronic component embedded substrate as claimed in claim 2,
wherein a thickness of the third insulating layer is locally increased at a part overlapping the first via conductor, and
wherein a part of the third insulating layer that contacts an upper surface of the first via conductor is constituted by a resin material not containing a core material.

4. The electronic component embedded substrate as claimed in claim 1,
wherein an upper section of the first via that is positioned on a side close to the upper surface of the second insulating layer has a shape reduced in diameter in the depth direction, and
wherein a lower section of the first via that is positioned on a side close to the lower surface of the first insulating layer has a first section increased in diameter in the depth direction and a second section positioned closer to the lower surface of the first insulating layer than the first section and reduced in diameter in the depth direction.

5. The electronic component embedded substrate as claimed in claim 4, wherein at least a part of the first section is provided in the second insulating layer, and at least a part of the second section is provided in the first insulating layer.

6. The electronic component embedded substrate as claimed in claim 5, wherein a boundary between the first and second sections coincides with a boundary between the first and second insulating layers.

7. The electronic component embedded substrate as claimed in claim 1, wherein each of the first and second insulating layers is made of a resin material not containing a core material.

8. The electronic component embedded substrate as claimed in claim 7, wherein the first and second insulating layers are made of the same resin material.
